(19) United States
(12) Patent Application Publication
(10) Pub. No.: US 2009/0152677 A1
(43) Pub. Date: Jun. 18, 2009

(54) Semiconductor device and method for manufacturing semiconductor device

(75) Inventor: Mitsuhiro Horikawa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/292,814

(22) Filed: Nov. 26, 2008

(30) Foreign Application Priority Data
Dec. 18, 2007 (JP) 2007-325815

(51) Int. Cl. H01L 29/92; H01L 21/02

(52) U.S. Cl. 257/532; 438/381; 257/E29.343; 257/E21.008

(57) ABSTRACT

A semiconductor device including: a conducting plug provided in an interlayer insulating film over a semiconductor substrate; and a capacitor including a lower electrode provided over the conducting plug, the lower electrode being connected to the conducting plug, a dielectric film provided on the lower electrode, and an upper electrode provided on the dielectric film. The lower electrode includes a conducting pillar and a conducting outer layer provided over at least a circumferential side surface of the conducting pillar. The dielectric film covers at least a circumferential side surface of the lower electrode, and is contact with the conducting outer layer.

### BACKGROUND OF THE INVENTION

1. Field of the Invention

The invention relates to a semiconductor device including a capacitor and a method for manufacturing the semiconductor device.

2. Description of Related Art

The cells of DRAM (Dynamic Random Access Memory) can have various cell structures, including those shown, for instance, in SUNAMI Hideo, Nikkei Microdevices, Nikkei Business Publications, Inc., December Issue 1996, pp. 112-123. The cell structures include stack-type structures including stack capacitors and trench-type structures including trench-type capacitors. Both types of structure were developed in order to increase the surface area of the capacitor electrode.

In stack-type cells, cylindrical structures including a cylindrical storage electrode are common. The cylindrical structures include structures in which the only internal wall of the cylinder is used and structures in which both the internal and external walls are used.

When the diameter and height of the respective cylindrical structures is the same, the structure in which both the external and internal walls are used has the larger surface area and is therefore advantageous. However, the progress of miniaturization has made it impossible to ignore the film thicknesses of the electrodes and dielectric which form the capacitor, with respect to the diameter of the cylinder. As a result, it is difficult to use both the internal and external walls of the cylinder. Moreover, because it is necessary to remove an insulating film from between the cylinders during the capacitor manufacturing process, the cylinders are no longer supported and can break off, causing operating faults. Japanese Patent Laid-Open No. 2006-294992 describes a technique for solving this type of problem in capacitors having cylindrical constructions.

Structures which only make use of the internal wall of the cylinder are not subject to such manufacturing problems, and are comparatively simple to make. However, with increasing miniaturization, the problem of insufficient covering of the internal wall of the cylinder has emerged.

One capacitor structure which is not afflicted with the covering problem is a structure called a pedestal structure in which the surfaces of a columnar body are used. International Technology Roadmap for Semiconductors, 2006 Update, internet <URL:http://www.itrs.net/Links/2006Update/FinalToPost)07_FEP2006Update .pdf> has a roadmap based on the assumption that, from 2007 onwards, stack capacitors are to be of the pedestal type. However, pedestal-type capacitors also have the problem of the columnar bodies breaking because of a need to temporarily remove insulating film from between the columnar bodies during the capacitor manufacturing process.

In pedestal-type capacitor structures, the columnar body is a conducting body and the columnar body itself forms the electrode. To reduce leakage current in a capacitor, it is desirable that the band gap in the dielectric is large, and that the band offset with respect to the Fermi level of the electrode is large. The band offset is a physical constant determined by the dielectric material and the electrode material. Thus, the electrode material which forms the cylindrical body is required to have not only the mechanical strength required to prevent breakage during manufacture but also the desired electrical properties.

It is, however, not easy to satisfy this requirement because materials with excellent mechanical strength do not always have the required electrical properties. As described above, dielectrics which have a large band-gap give a reduced leakage current. However, the dielectrics which are actually used tend to have a small band-gap. A capacitance C is given by C=ε₀εᵣ (S/d). Here, ε₀ is the electrical permittivity of a vacuum, εᵣ is the relative electrical permittivity of the dielectric, S is the area of the electrode, and d is the thickness of the dielectric. Since tunnel current becomes a problem when the dielectric is made thin and since miniaturization is difficult when the area S of the electrode is made large, it is necessary to use a dielectric having a large relative electrical permittivity εᵣ. However, dielectrics having a large relative electrical permittivity εᵣ tend to have a narrow band-gap. As a consequence, there is only a narrow range of options for electrode materials which give a band offset for which leakage current is sufficiently suppressed.

### SUMMARY

In one embodiment, there is provided a semiconductor device including:

a conducting plug provided in an interlayer insulating film over a semiconductor substrate; and

a capacitor including
a lower electrode provided over the conducting plug, the lower electrode being connected to the conducting plug,
a dielectric film provided on the lower electrode, and
an upper electrode provided on the dielectric film,

wherein the lower electrode includes a conducting pillar and a conducting outer layer provided over at least a circumferential side surface of the conducting pillar, and

the dielectric film covers at least a circumferential side surface of the lower electrode, the dielectric film being contact with the conducting outer layer.

In another embodiment, there is provided the above-described semiconductor device, wherein a band offset between a material of the conducting outer layer and a material of the dielectric film is larger than a band offset between a material of the conducting pillar and the material of the dielectric film.

In another embodiment, there is provided any one of the above-described semiconductor devices, wherein a band offset between a material of the conducting outer layer and a material of the dielectric film is at least 1 eV.

In another embodiment, there is provided any one of the above-described semiconductor devices, wherein the conducting outer layer is made of Ru.

In another embodiment, there is provided any one of the above-described semiconductor devices, wherein the conducting pillar is made of a material selected the group consisting of W, RuO₂, and impurity-containing polycrystalline silicon.

In another embodiment, there is provided any one of the above-described semiconductor devices wherein the dielectric film is made of SrTiO₃.

In another embodiment, there is provided any one of the above-described semiconductor devices wherein the lower electrode includes a lower portion extending to a bottom end of the lower electrode, the lower portion having a larger area of a cross-section parallel to a substrate plane than that of an upper portion of the lower electrode extending to a top end thereof.

In another embodiment, there is provided a method for manufacturing a semiconductor device, including:

forming a conducting plug in a first interlayer insulating film over a semiconductor substrate;

forming a second interlayer insulating film over the conducting plug and the first interlayer insulating film;

forming a hole penetrating the second interlayer insulating film to reach the conducting plug;

forming a first conducting film over a surface including an internal wall of the hole, forming a second conducting film to fill the hole, and removing the first conducting film and the second conducting film outside the hole, thereby obtaining in the hole a lower electrode including a conducting pillar made of the second conducting film, and a conducting outer layer including the first conducting film covering a circumferential side surface of the conducting pillar;

removing the second interlayer insulating film to expose the lower electrode;

forming a dielectric film covering the lower electrode; and

forming a conducting film for an upper electrode on the dielectric film such that the conducting film covers the lower electrode.

In another embodiment, there is provided the above-described method for manufacturing a semiconductor device, further including:

removing a top end portion of the second conducting film in the hole to form a depression at an opening of the hole when or after removing the first conducting film and the second conducting film outside the hole;

forming a third conducting film to fill the depression; and

removing the third conducting film outside the depression,

thereby obtaining the lower electrode including, in the hole,
the conducting pillar made of the second conducting film, and
the conducting outer layer including the first conducting film covering the circumferential side surface of the conducting pillar, and the third conducting film covering a top surface of the conducting pillar.

In another embodiment, there is provided any one of the above-described methods for manufacturing a semiconductor device, wherein the second interlayer insulating film is a multilayer film including a lower layer insulating film extending to a bottom surface of the second interlayer insulating film, and an upper layer insulating film formed over the lower layer insulating film, the upper layer extending to a top surface of the second interlayer insulating film;

the lower layer insulating film is made of a material being able to be etched at an etching rate higher than an etching rate of the upper insulating film in a subsequent etching; and

after forming the hole in the second interlayer insulating film made up of the multilayer film to reach the conducting plug, the etching is performed in the hole to cause recessing in a side wall of the lower insulating film beyond a side wall of the upper insulating film, thereby expanding an internal diameter of a lower portion of the hole.

In another embodiment, there is provided a method for manufacturing a semiconductor device, including:

forming a conducting plug in a first interlayer insulating film over a semiconductor substrate;

forming a second interlayer insulating film over the conducting plug and the first interlayer insulating film;

forming a hole penetrating the second interlayer insulating film to reach the conducting plug;

forming a first conducting film to fill the hole to form a conducting pillar made of the first conducting film in the hole;

removing the second interlayer insulating film to expose the conducting pillar;

forming a second conducting film covering the conducting pillar to form a lower electrode including the conducting pillar made of the first conducting film, and a conducting outer layer including the second conducting film covering the top surface and the circumferential side surface of the conducting pillar;

forming a dielectric film covering the lower electrode; and

forming a conducting film for an upper electrode on the dielectric film such that the conducting film covers the lower electrode.

In another embodiment, there is provided the above-described method for manufacturing a semiconductor device, wherein the first conducting film is an impurity-containing polycrystalline silicon film;

the second conducting film is a metal-containing film; and

the method further including forming a first barrier conducting film covering the exposed conducting pillar before forming the second conducting film.

In another embodiment, there is provided any one of the above-described methods for manufacturing a semiconductor device, wherein the conducting plug is formed using an impurity-containing polycrystalline silicon;

the first conducting film is formed using a metal-containing film; and

the method further including forming a second barrier conducting film covering at least a bottom surface of the hole before forming the first conducting film to fill the hole, thereby obtaining in the hole a conducting pillar made up of the first conducting film, at least a bottom surface of the conducting pillar being covered with the second barrier conducting layer.

In another embodiment, there is provided any one of the above-described methods for manufacturing a semiconductor device, wherein the second interlayer insulating film is a multilayer film including a lower layer insulating film extending to a bottom surface of the second interlayer insulating film and an upper layer insulating film formed over the lower layer insulating film, the upper layer extending to a top surface of the second interlayer insulating film;

the lower layer insulating film is made of a material being able to be etched at an etching rate higher than an etching rate of the upper insulating film in a subsequent etching; and

after forming the hole in the second interlayer insulating film made up of the multilayer film to reach the conducting plug, the etching is performed in the hole to cause recessing in a side wall of the lower insulating film beyond a side wall of the upper insulating film, thereby expanding an internal diameter of a lower portion of the hole.

According to exemplary embodiments, it is possible to provide a semiconductor device which has a capacitor structure with excellent electrical properties and suppresses operating faults caused by capacitor form.

### BRIEF DESCRIPTION OF THE DRAWINGS

The features and advantages of the present invention will be more apparent from the following description of certain preferred embodiments taken in conjunction with the accompanying drawings, in which:

FIG. 1A is a cross-sectional diagram showing a process for describing an exemplary embodiment of a method for manufacturing a semiconductor device;

FIG. 1B is a cross-sectional diagram showing a process subsequent to the manufacturing process shown in FIG. 1A;

FIG. 1C is a cross-sectional diagram showing a process subsequent to the manufacturing process shown in FIG. 1B;

FIG. 1D is a cross-sectional diagram showing a process subsequent to the manufacturing process shown in FIG. 1C;

FIG. 1E is a cross-sectional diagram showing a process subsequent to the manufacturing process shown in FIG. 1D;

FIG. 1F is a cross-sectional diagram showing a process subsequent to the manufacturing process shown in FIG. 1E;

FIG. 1G is a cross-sectional diagram showing a process subsequent to the manufacturing process shown in FIG. 1F;

FIG. 1H is a cross-sectional diagram showing a process subsequent to the manufacturing process shown in FIG. 1G;

FIG. 1I is a cross-sectional diagram showing a process subsequent to the manufacturing process shown in FIG. 1H;

FIG. 2 is a cross-sectional diagram showing a process for describing another exemplary embodiment of the method for manufacturing the semiconductor device;

FIG. 3A is a cross-sectional diagram showing a process for describing a further exemplary embodiment of the method for manufacturing the semiconductor device;

FIG. 3B is a cross-sectional diagram showing a subsequent process of the manufacturing process shown in FIG. 3A;

FIG. 3C is a cross-sectional diagram showing a subsequent process of the manufacturing process shown in FIG. 3B;

FIG. 3D is a cross-sectional diagram showing a subsequent-process of the manufacturing process shown in FIG. 3C;

FIG. 4A is a cross-sectional diagram showing a process for describing a further exemplary embodiment of the method for manufacturing the semiconductor device;

FIG. 4B is a cross-sectional diagram showing a subsequent process of the manufacturing process shown in FIG. 4A;

FIG. 4C is a cross-sectional diagram showing a subsequent process of the manufacturing process shown in FIG. 4B;

FIG. 4D is a cross-sectional diagram showing a subsequent process of the manufacturing process shown in FIG. 4C;

FIG. 4E is a cross-sectional diagram showing a subsequent process of the manufacturing process shown in FIG. 4D;

FIG. 5A is a cross-sectional diagram showing a process for describing a further exemplary embodiment of the method for manufacturing the semiconductor device;

FIG. 5B is a cross-sectional diagram showing a subsequent process of the manufacturing process shown in FIG. 5A; and

FIG. 5C is a cross-sectional diagram showing a subsequent process of the manufacturing process shown in FIG. 5B.

### DETAILED DESCRIPTION OF THE PREFERRED EMBODIMENTS

A semiconductor device of an exemplary embodiment includes a conducting plug provided in an interlayer insulation film on a semiconductor substrate, and a capacitor having a lower electrode provided on the conducting plug such that the electrode connects with the conducting plug, a dielectric film provided on the lower electrode, and an upper electrode provided on the dielectric film. The semiconductor device can be used in semiconductor memory apparatus such as DRAM (Dynamic Random Access Memory).

The lower electrode of the capacitor includes a conducting pillar and a conducting outer layer provided at least on a circumferential side surface of the conducting pillar. The dielectric film of the capacitor is then provided so as to cover the circumferential side surface of the conducting pillar, that is, the lower electrode, the dielectric film being in contact with the conducting outer layer.

With this configuration, the material of the conducting outer layer is not subject to the mechanical strength restrictions of the lower electrode, and hence a material which has a large band offset with respect to the dielectric film can be used. Consequently, it is possible to provide a semiconductor device which includes capacitors with suppressed leakage current and excellent electrical properties. Further, the material of the conducting pillar is not subject to requirements for the electrical properties of the capacitors, and hence a material which has a high mechanical strength can be used. Consequently, it is possible to prevent lower electrode breakage during manufacture.

In the above-described capacitor structure, construction materials are preferably selected so that the band offset between the material of the conducting outer layer and the material of the dielectric film is larger than the band offset between the material of the conducting pillar and the material of the dielectric film. It is preferable that the band offset (conduction band offset) between the material of the conducting outer layer and the material of the dielectric film is at least 1 eV.

The material of the conducting outer layer is preferably a conducting material for which it is easy to secure a large band offset with respect to the dielectric film. Such materials include Ru, Ir, Pt, RuO₂, IrO₂, SrRuO₃, MoN, Ni, WO_{X}, MoOₓ and TaCNO.

In order to make the lower electrode less likely to break during manufacture, it is desirable that the lower electrode has a form which is difficult to break and that the material used for the conducting pillar which forms the lower electrode has, in itself, a high strength. For the material of the conducting pillar, it is preferable to use a material which has a higher mechanical strength than the material used for the conducting outer layer so that the lower electrode is more difficult to break during manufacture. Examples of materials which can be used include W, WSiₓ, RuO₂ and impurity-containing polycrystalline silicon.

For the material of the dielectric film, it is again preferable to use a dielectric having a large bandgap and a large band offset with respect to the conducting outer layer. Such materials include SrTiO₃, BaSrTiO₃, BaHfOₓ, HfTaOₓ, LaTiOₓ, YTiOₓ, SrNbO_{X} and YNbOₓ.

The following gives further descriptions of the exemplary embodiments with reference to manufacturing examples and the drawings.

### First Exemplary Embodiment

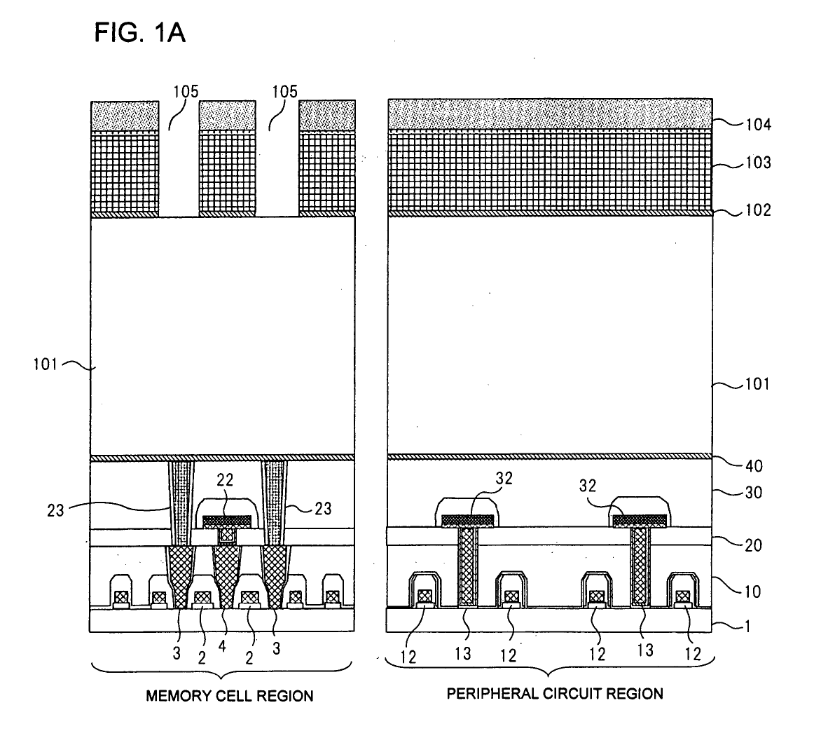

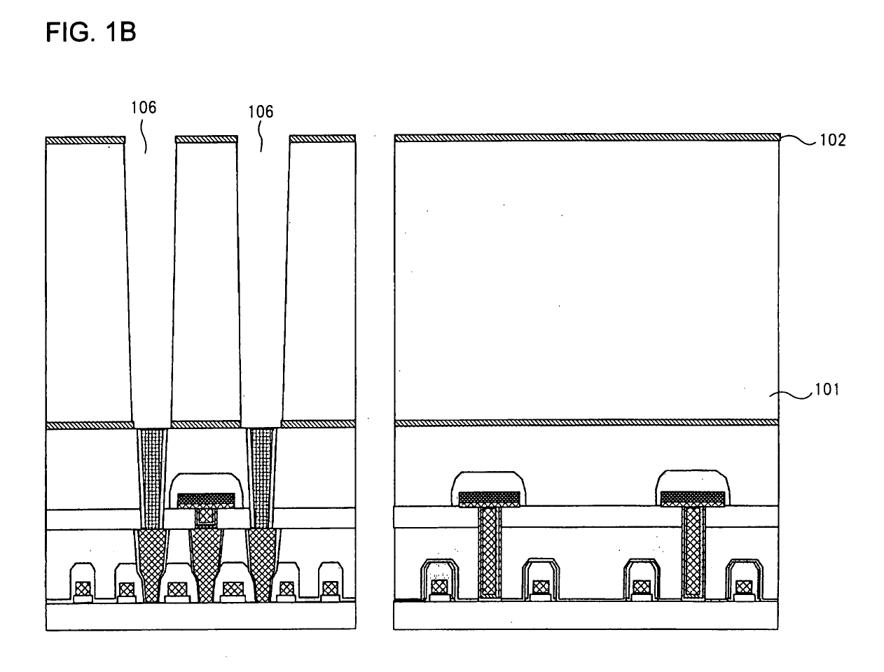

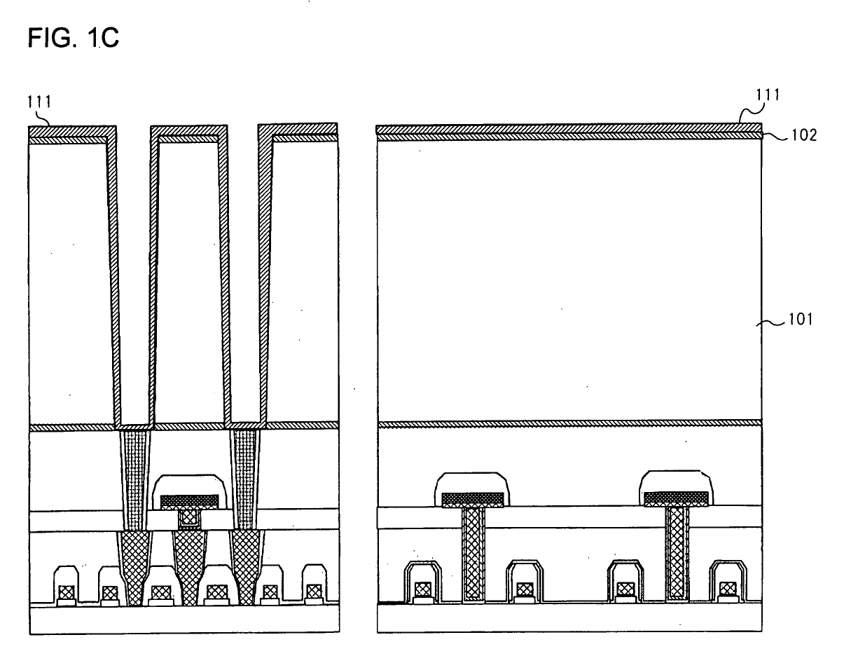

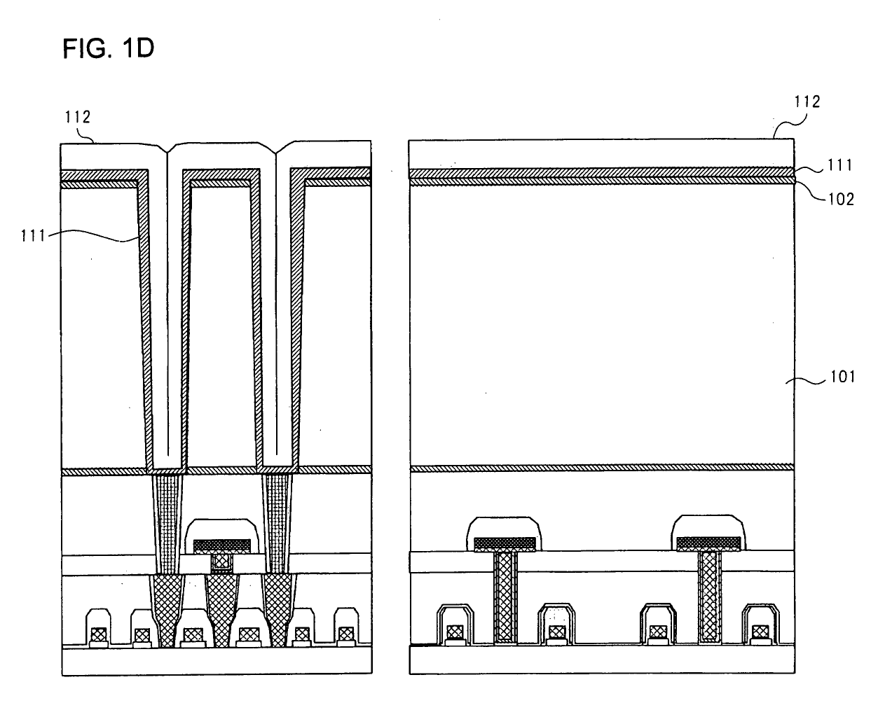

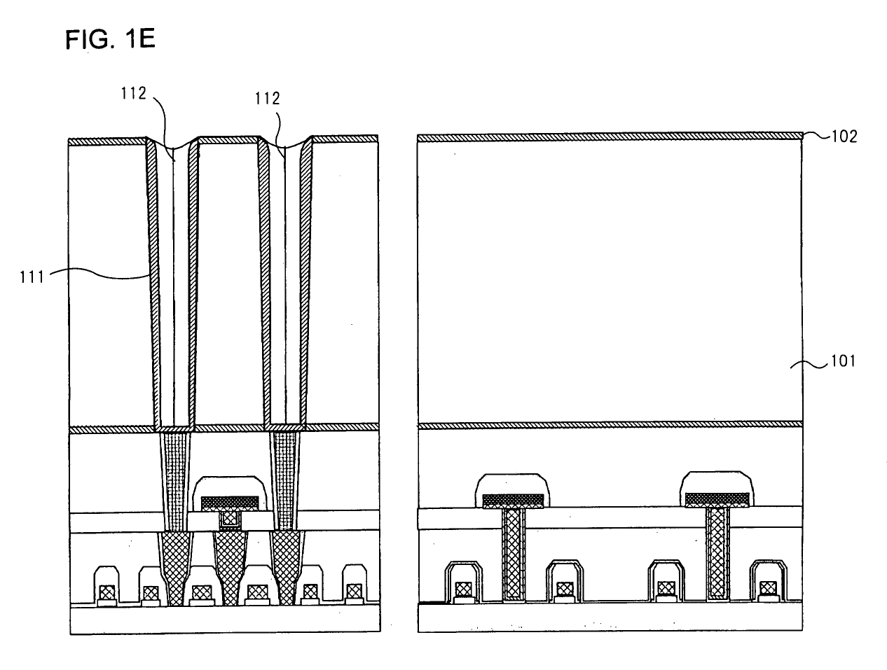

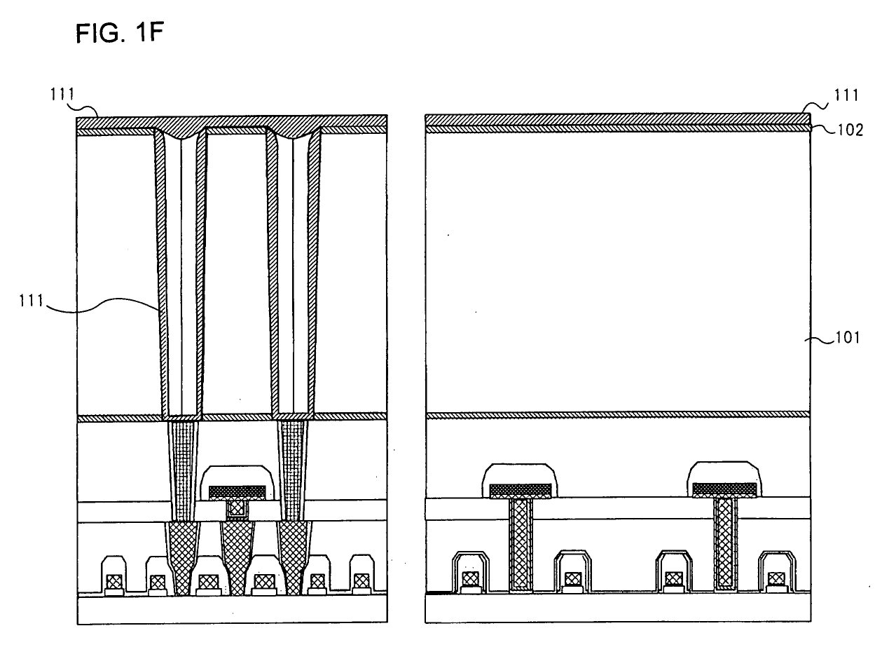

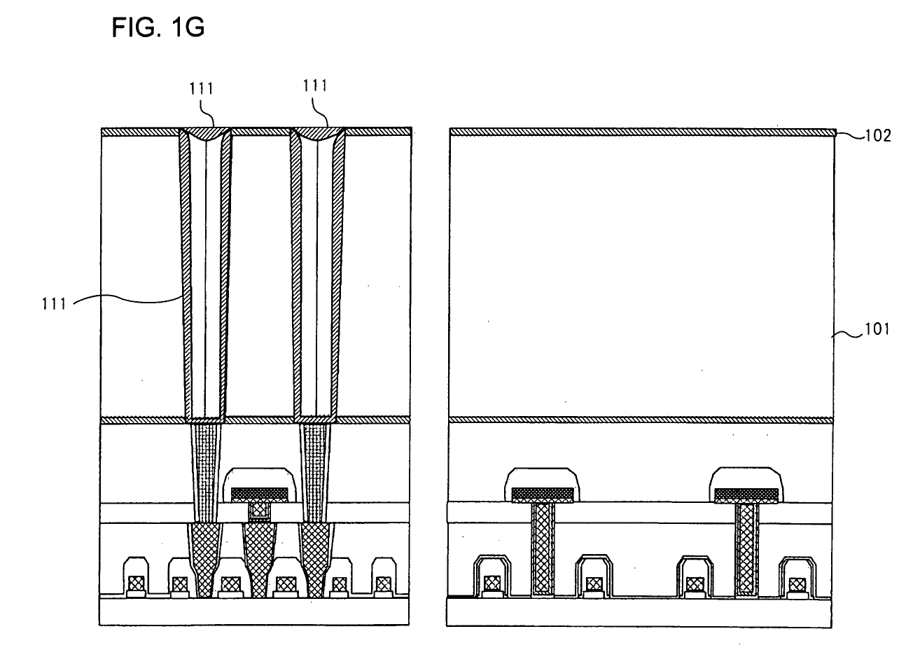

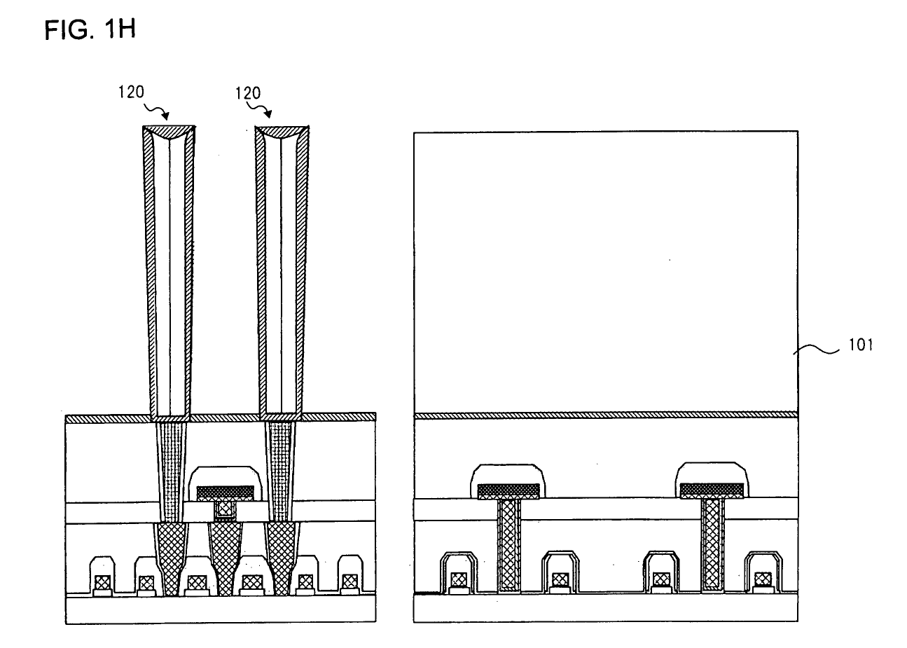

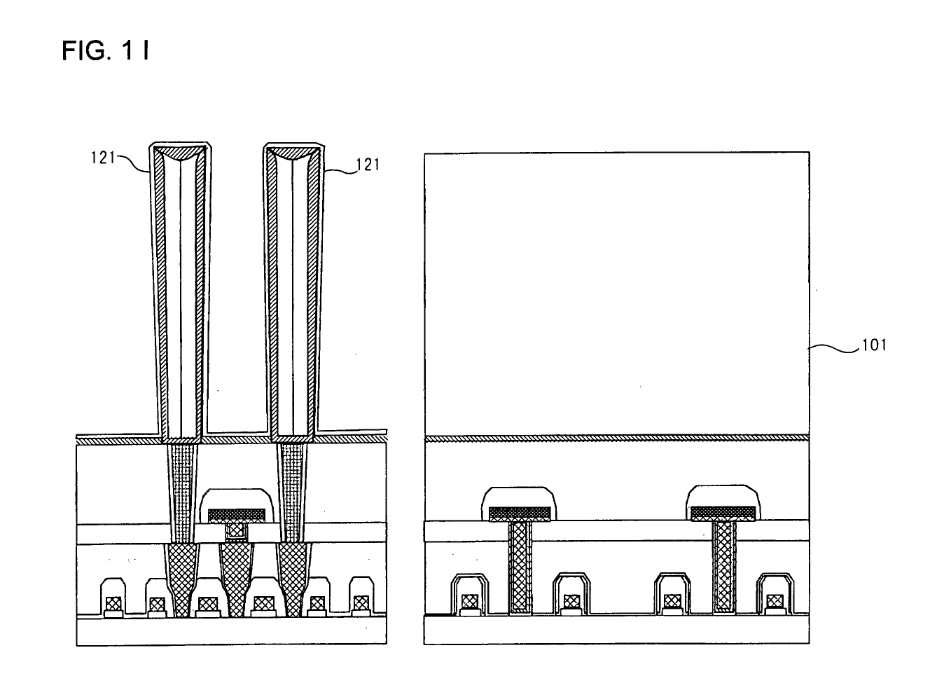

By usual methods, memory cells and peripheral circuits are formed on a silicon substrate which includes an element isolation region (not shown in the drawings). The left side of FIG. 1A shows a memory-cell region and the right side of FIG. 1A shows a peripheral circuit region. Reference numeral 1 denotes the silicon substrate, reference numerals 10, 20 and 30 denote interlayer insulating films made of silicon oxide, and reference numeral 40 denotes a silicon nitride film. Reference numeral 2 denotes a gate electrode (word line) of the memory cell transistor and reference numerals 3 and 4 denote contact plugs. Reference numeral 22 denotes a bit line, reference numeral 23 denotes a via plug which is to connect to a storage electrode (lower electrode) of a capacitor formed later. Reference numeral 12 denotes a gate electrode of a transistor of the peripheral circuit, reference numeral 13 denotes a contact plug, and reference numeral 32 denotes a wiring layer.

After forming interlayer insulating film 101 made of silicon oxide, and forming thereon silicon nitride film 102, hard mask 103 and resist film 104 are formed. Then, through use of usual lithography and etching techniques, openings 105 are formed at positions where the storage electrodes (lower electrodes) are to be formed.

Next, dry etching is performed using hard mask 103 and resist film 104 used as a mask to form holes 106 which reach via plugs 23, as shown in FIG. 1B.

Next, first conducting film 111 is formed so as to cover an entire surface including the internal walls of holes 106, as shown in FIG. 1C. First conducting film 111 is to form, at a later stage, a conducting outer layer of a storage electrode. First conducting film 111 directly contacts the dielectric film and provides the required electrical properties.

Next, second conducting film 112 is formed so as to fill holes 106, as shown in FIG. 1D. The portions of second conducting film 112 filling holes 106 form columnar bodies (pedestals), and provide the required mechanical strength of the storage electrodes.

Next, first conducting film 111 and second conducting film 112 that are located outside holes 106 are removed by CMP (Chemical Mechanical Polishing). Consequently, the first conducting film and the second conducting film only remain in holes 106, as shown in FIG. 1E. At this point, second conducting film 112 within holes 106 is excessively removed so that depressions are formed at the openings of the holes. By adjusting the polishing conditions and the composition of the polishing liquid to control a ratio between the polishing rate for the interlayer insulating film (or the interlayer insulating film and the first conducting film) and the polishing rate of the second conducting film, it is possible to control the form of the depressions. Alternatively, the depressions may be formed by selectively wet etching the second conducting film after the CMP. When forming the depressions, the amount of removing the first conducting film is preferably approximately the same as or less than the amount of removing the second conducting film.

Next, first conducting film 111 is formed for a second time so as to fill the depressions at the openings of the holes, as shown in FIG. 1F.

Next, the first conducting film located outside the depressions is removed by performing CMP, leaving the first conducting film in the depressions, as shown in FIG. 1G. As a result, storage electrodes having a cylindrical body (pedestal) formed from the second conducting film and completely covered by the first conducting film are formed in holes 106.

Next, after silicon nitride film 102 has been removed, the peripheral circuit region is masked and interlayer insulating film 101 of the memory cell region is removed by wet etching using a hydrofluoric acid solution. As a result, storage electrode 120 is exposed as shown in FIG. 1H.

Next, dielectric film 121 is formed on storage electrodes 120, as shown in FIG. 11. Dielectric film 121 contacts first conducting film 111 on the circumferential side surfaces and top surfaces of the storage electrodes.

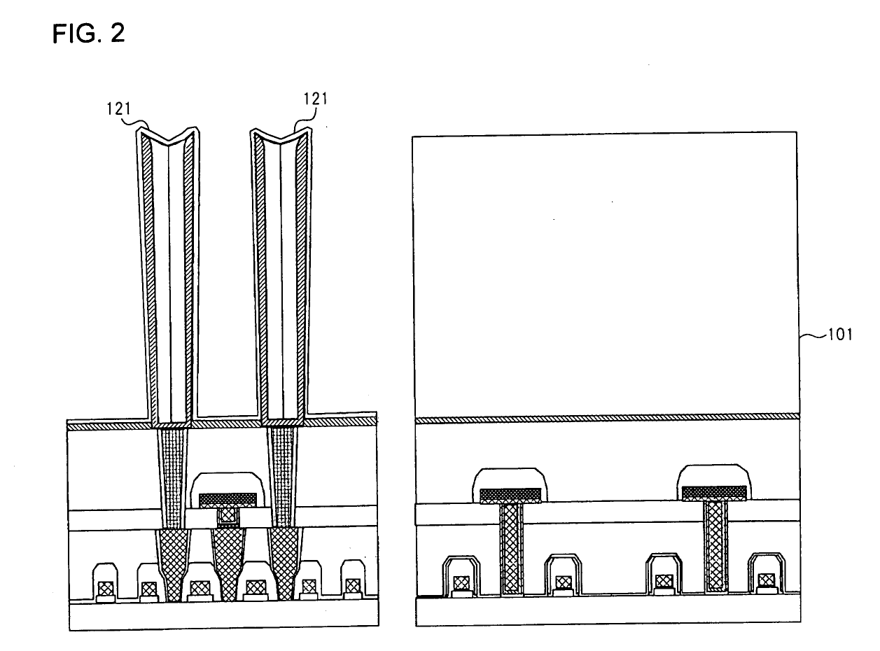

Note that it is also possible to omit the processes shown in FIG. 1F and FIG. 1G and produce the structure shown in FIG. 2 in which first conducting film 111 is not provided on the top surface of the pedestal that is formed from second conducting film 112. In this case, dielectric film 121 contacts first conducting film 111 that forms the circumferential side surface of the storage electrode.

SrTiO₃ can be used in dielectric film 121, Ru can be used in first conducting film 111, and W or RuO₂ can be used in second conducting film 112. Dielectric film 121 can be formed by a film forming method in usual capacitor manufacturing methods, and first conducting film 111 can be formed using CVD (Chemical Vapor Deposition), ALD (Atomic Layer Deposition) or SCFD (super-critical fluid deposition). The second conducting film 112 can be formed using CVD, ALD, SCFD or a plating method.

Next, a conducting film that is to form the opposing electrode (upper electrode) is formed on dielectric film 121 by a film forming method in usual capacitor manufacturing methods, thereby producing a capacitor. By usual methods for manufacturing semiconductor devices, subsequent processes are carried out to form a semiconductor device having the desired structure.

### Second Exemplary Embodiment

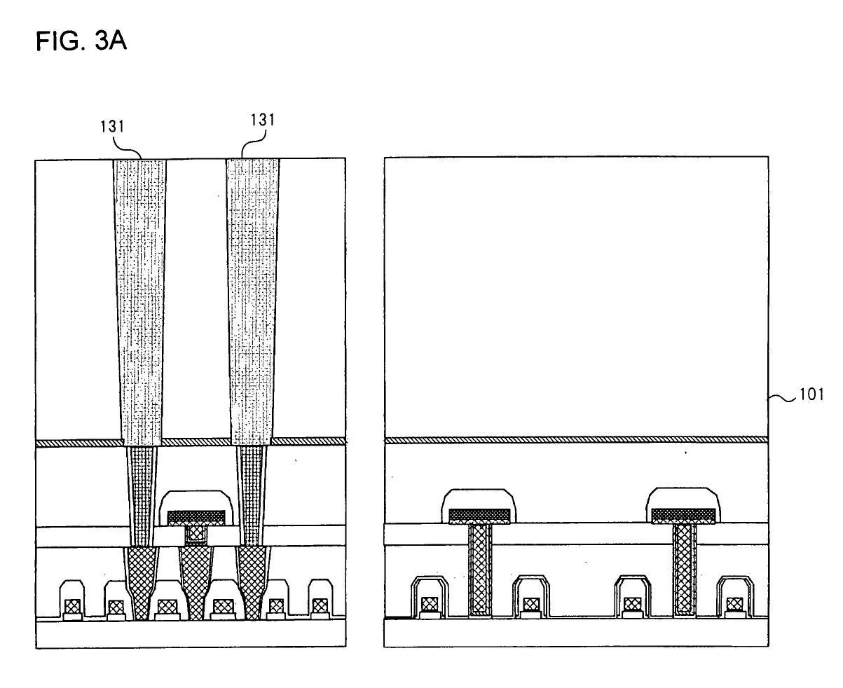

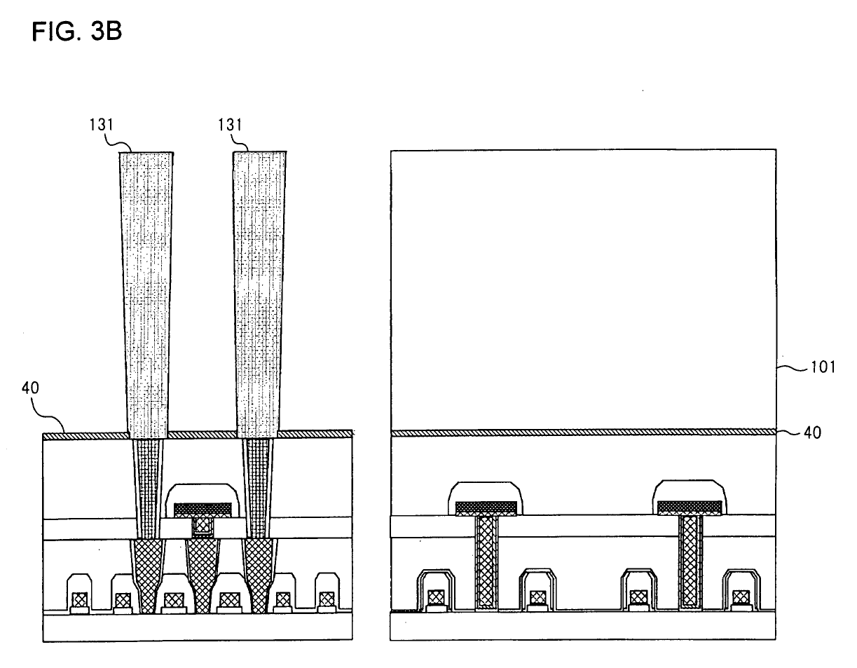

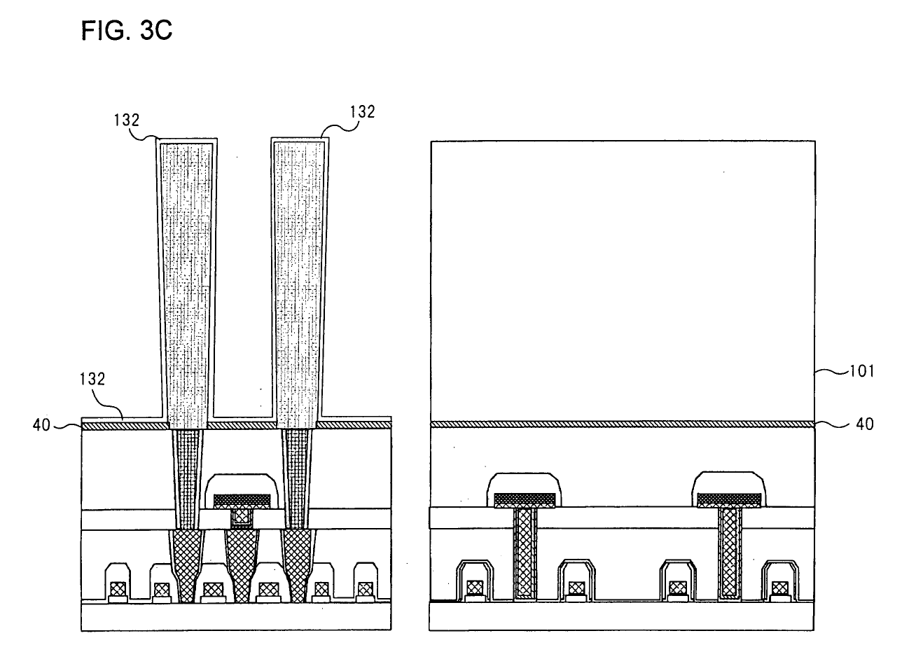

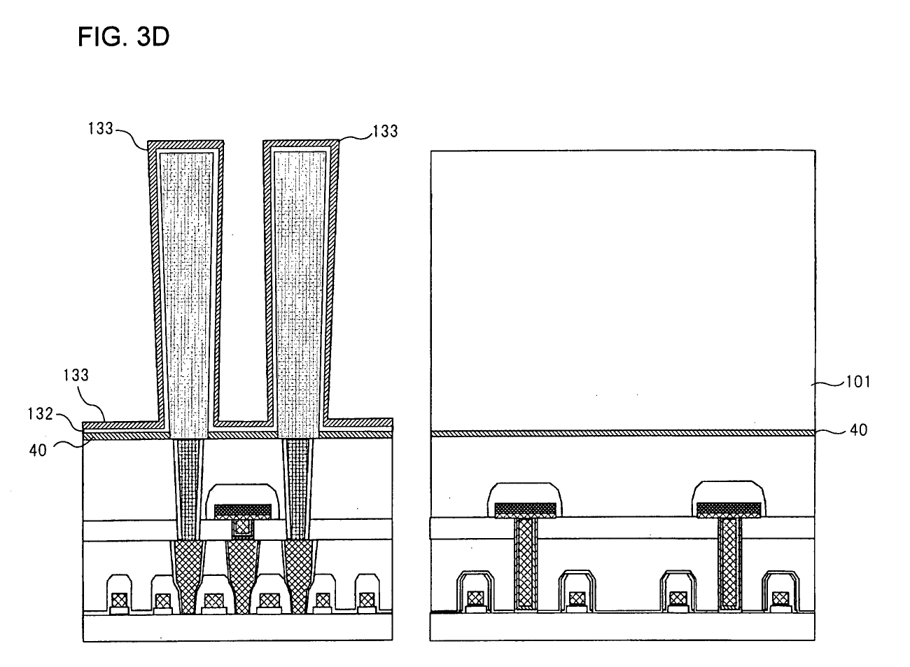

The following manufacturing method shown in FIGS. 3A to 3D is an example of the case in which the pedestal is formed using polycrystalline silicon.

After carrying out the processes shown in FIGS. 1A and 1B of the first exemplary embodiment, an impurity-containing polycrystalline silicon film is formed so as to fill holes 106.

Next, the polycrystalline silicon film located outside the holes is removed by performing CMP, and then silicon nitride film 102 is removed. Thus, a structure is obtained in which holes 106 are filled with polycrystalline silicon 131, as shown in FIG. 3A. Polycrystalline silicon 131 in holes 106 forms pedestals.

Next, interlayer insulating film 101 of the memory cell region is removed to expose the pedestals that are formed from polycrystalline silicon 131, as shown in FIG. 3B.

A film of barrier metal 132 is formed on the pedestals formed from polycrystalline silicon 131, as shown in FIG. 3C. Metal film 133 is then formed on barrier metal 132, as shown in FIG. 3D. Consequently, a storage electrode is obtained that is made up of the pedestal formed from the polycrystalline silicon 131, and the metal film 133 provided, via barrier metal 132, on the top surface and circumferential side surface of the pedestal.

Next, after removing the barrier metal and the metal film on silicon nitride film 40 between the storage electrodes by etching back, the capacitor can be obtained by forming a dielectric film and then forming on the dielectric film a conducting film which is to form the opposing electrode (upper electrode). The same materials as are used in the first exemplary embodiment can be used for the dielectric film and the opposing electrode.

According to the present exemplary embodiment, a metal film which forms over the pedestal can be selected without being subject to restrictions as regards reactivity with polycrystalline silicon. Thus, a metal film which provides the required electrical properties can be formed over the pedestal made of polycrystalline silicon which provides the required mechanical strength.

When reaction between the polycrystalline silicon and the metal film is not a problem, a structure not including the barrier metal can be obtained.

### Third Exemplary Embodiment

The object of the present exemplary embodiment is to improve the strength of the storage electrode.

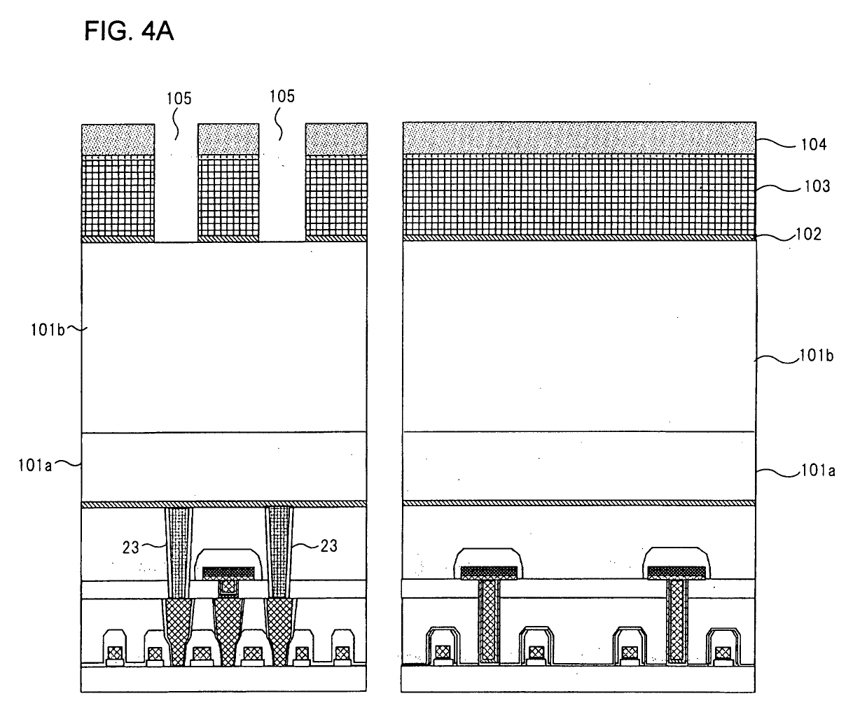

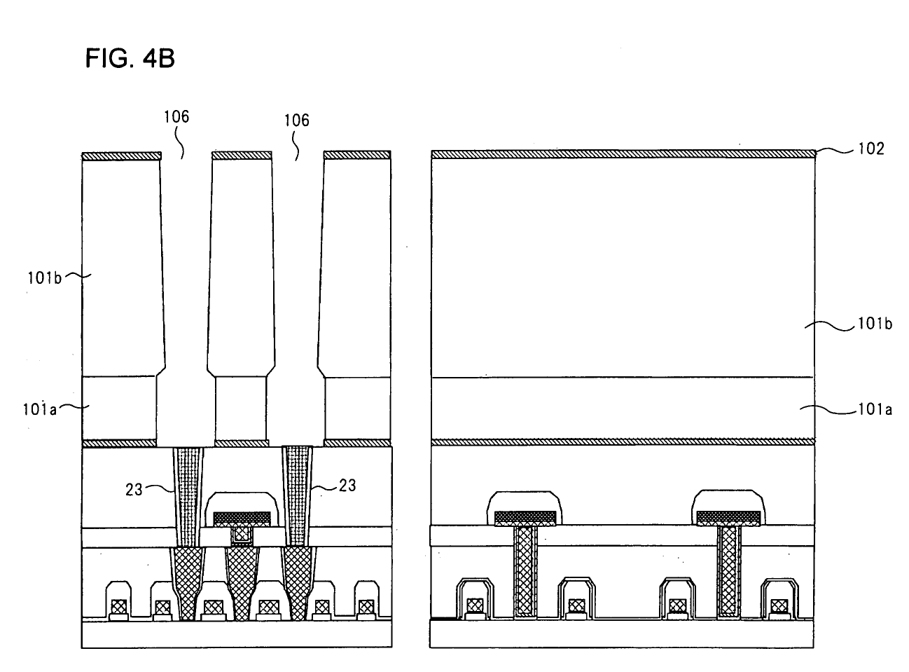

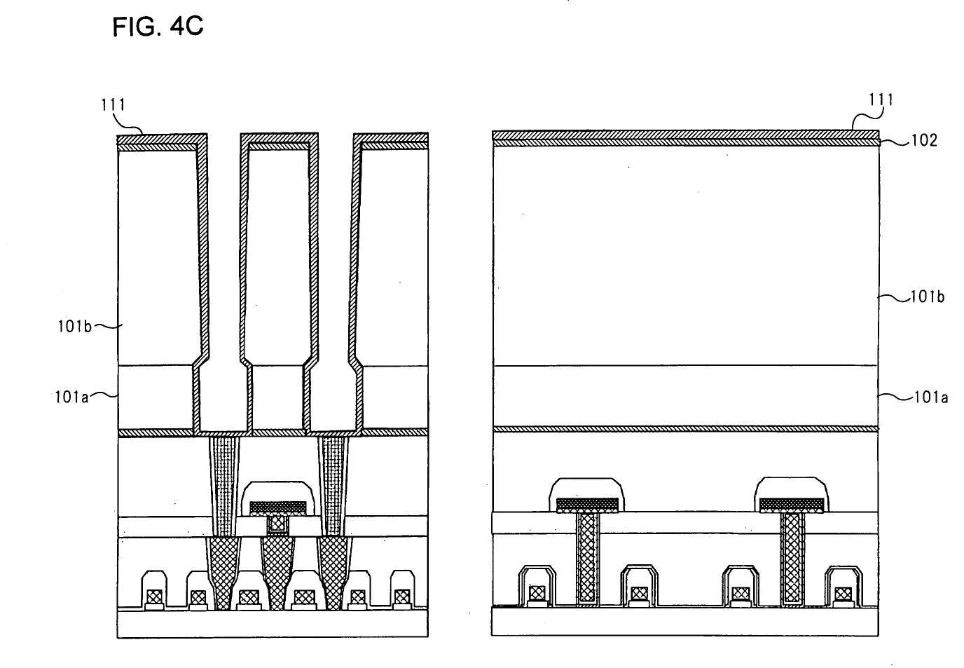

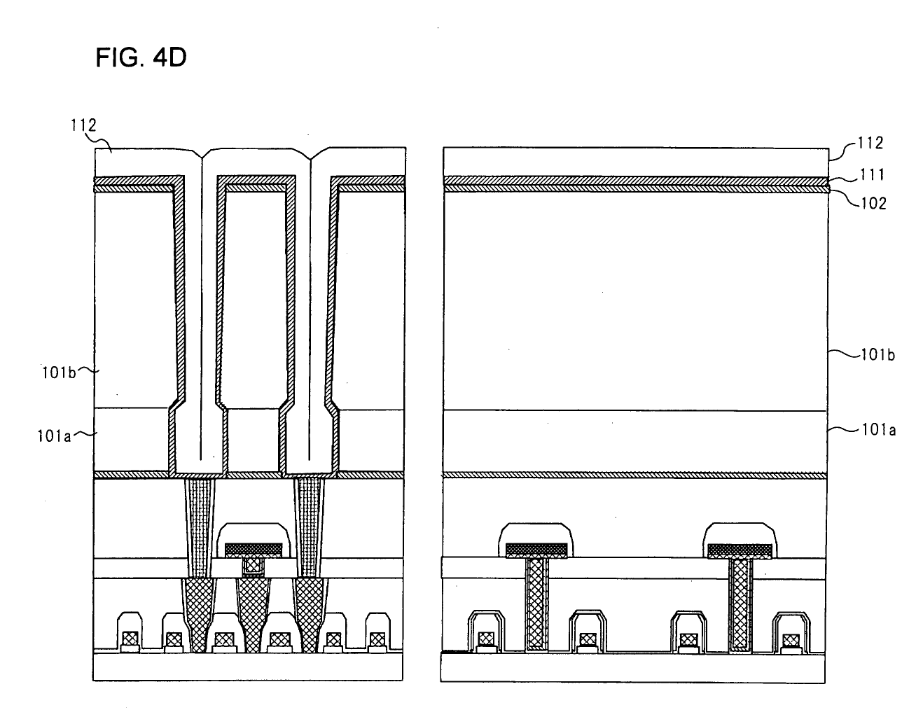

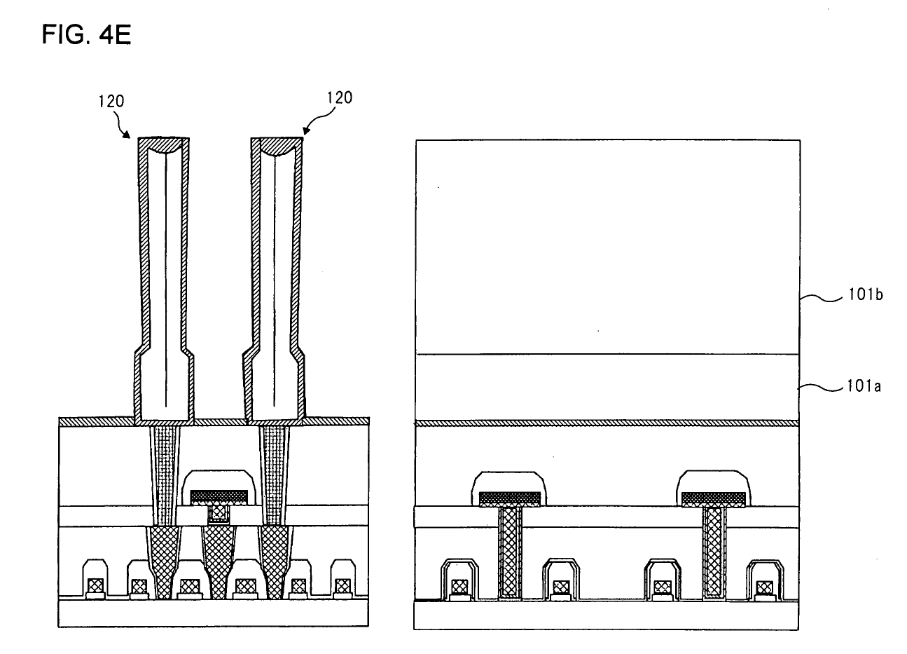

A structure shown in FIG. 4A is prepared in the same way as in the first exemplary embodiment except that interlayer insulating films 101a and 101b having different etching rates each other.

Next, dry etching is performed using hard mask 103 and resist film 104 as a mask to form holes 106 which reach via plugs 23.

Next, in holes 106, the side walls of interlayer insulating film 101a are recessed beyond the side walls of interlayer insulating film 101b by wet etching, so as to expand the internal diameter of the bottom portion of the holes 106, as shown in FIG. 4B. Interlayer insulating film 101a may be a BPSG (Boron Phosphorous Silicate Glass) film or PSG (Phospho Silicate Glass) film, interlayer insulating film 101b may be a silicon oxide film, and the etching liquid may be hydrofluoric acid solution.

Next, storage electrode 120 is formed in the same way as in the first exemplary embodiment, and exposed by removing interlayer insulating films 101a and 101b, as shown in FIGS. 4C to 4E. As a result, a stable form in which the lower part of the storage electrode is wide can be obtained, as shown in FIG. 4E.

Subsequently, in the same way as in the first exemplary embodiment, the capacitor can be produced by forming the dielectric film, and forming a conducting film which is to become the opposing electrode (upper electrode) on the dielectric film.

The hole formation process of the present exemplary embodiment may also be applied to the second exemplary embodiment.

### Fourth Exemplary Embodiment

The present embodiment in an example of manufacture for the case in which the pedestal of the storage electrode (lower electrode) is formed using a metal and plugs 23 connected to the storage electrodes are formed using polycrystalline silicon. To prevent reaction between the metal of the storage electrode and the polycrystalline silicon a barrier metal is disposed therebetween. Examples of such a barrier metal include TiN, TaN, TiAlN, TaAlN and TaSiN.

First, holes 106 are formed in interlayer insulating film 101 in the same way as in the first exemplary embodiment, as shown in FIG. 1B. At this point, plugs 23 are formed using impurity-containing polycrystalline silicon in accordance with a usual method.

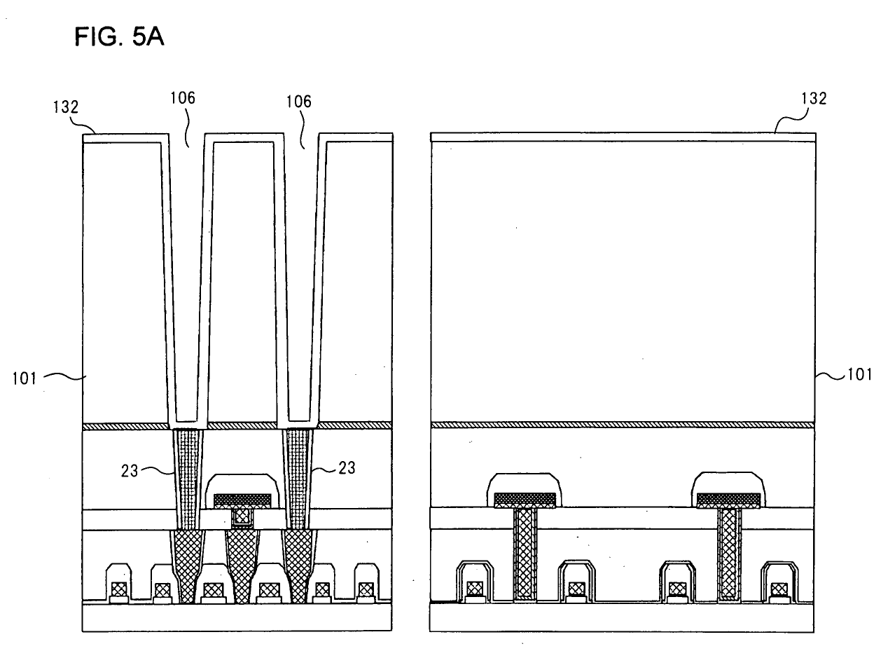

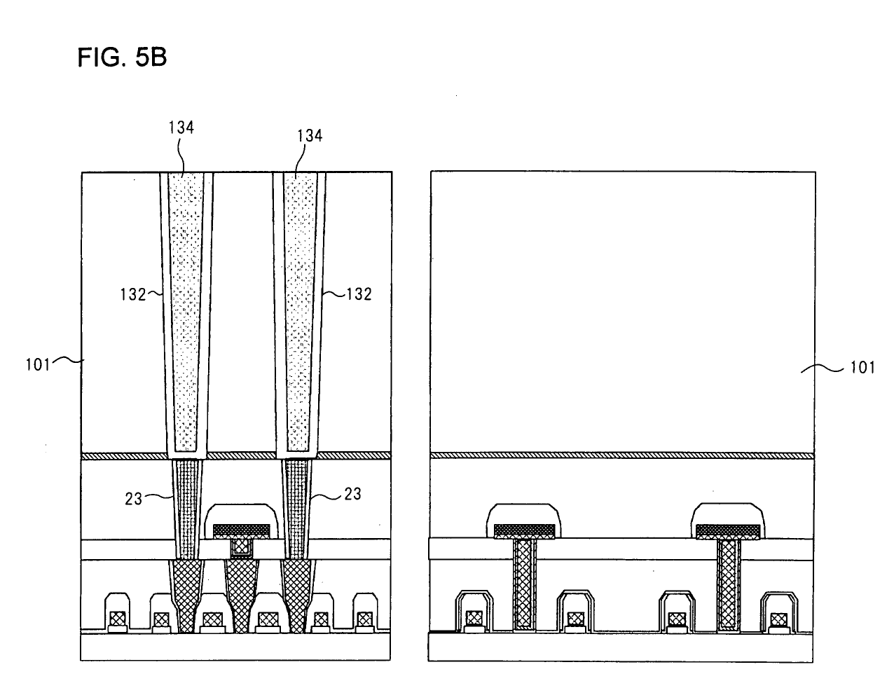

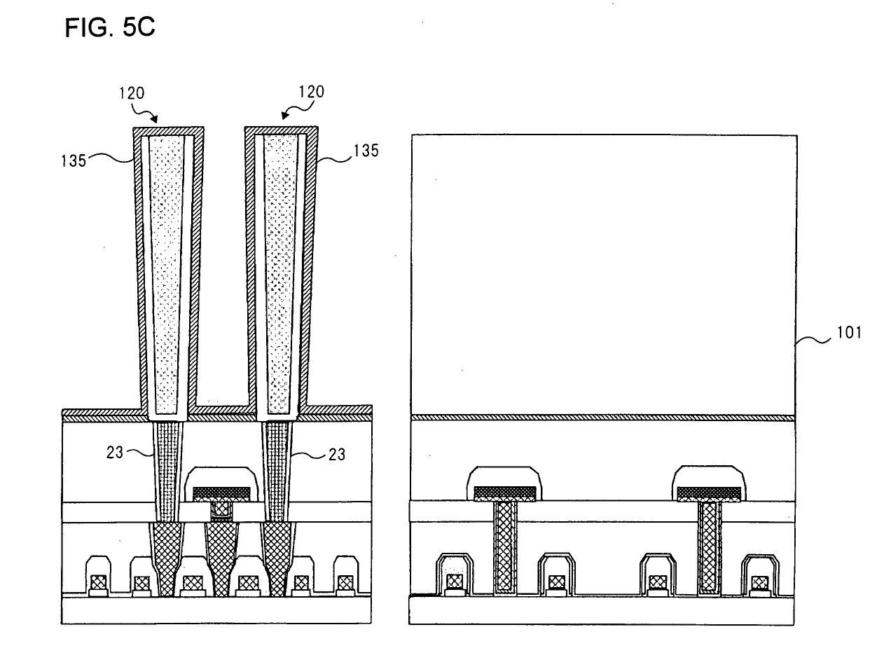

Next, after removing silicon nitride film 102, barrier metal 132 is formed as a film which covers at least a bottom surface of holes 106, as shown in FIG. 5A. To form barrier metal 132, CVD or ALD can be used. Also, since it is sufficient to cover the top surface of plug 23, PVD (Physical Vapor Deposition) can also be used.

Next, a metal layer is formed so as to fill holes 106. Then, the metal layer and barrier metal 132 that are located outside holes 106 are removed by performing CMP, thereby forming pedestals from metal 134 in holes 106, as shown in FIG. 5B.

Next, interlayer insulating film 101 is removed, and conducting film 135 is formed so as to cover the pedestal, as shown in FIG. 5C. As a result, storage electrodes 120 are obtained which have pedestals formed from metal 132, barrier metal 132 that cover the bottom surfaces and circumferential side surfaces of the pedestals, and conducting film 135 that cover the top surfaces and circumferential side surfaces of the pedestals. The storage electrodes 120 are connected to plugs 23 via barrier metal 132.

Next, after removing conducting film 135 between storage electrodes 120 by etching back, the capacitor can be obtained by forming the dielectric film in accordance with usual methods, and forming a conducting film which is to become the opposing electrode (upper electrode) on the dielectric film. The same materials as are used in the first exemplary embodiment can be used for the dielectric film and the opposing electrode.

It is apparent that the present invention is not limited to the above embodiments, but may be modified and changed without departing from the scope and spirit of the invention.

What is claimed is:

1. A semiconductor device comprising:
a conducting plug provided in an interlayer insulating film over a semiconductor substrate; and
a capacitor comprising
a lower electrode provided over the conducting plug, the lower electrode being connected to the conducting plug,
a dielectric film provided on the lower electrode, and
an upper electrode provided on the dielectric film,
wherein the lower electrode comprises a conducting pillar and a conducting outer layer provided over at least a circumferential side surface of the conducting pillar, and
the dielectric film covers at least a circumferential side surface of the lower electrode, the dielectric film being contact with the conducting outer layer.

2. The semiconductor device according to claim 1, wherein a band offset between a material of the conducting outer layer and a material of the dielectric film is larger than a band offset between a material of the conducting pillar and the material of the dielectric film.

3. The semiconductor device according to claim 1, wherein a band offset between a material of the conducting outer layer and a material of the dielectric film is at least 1 eV.

4. The semiconductor device according to claim 1, wherein the conducting outer layer is made of Ru.

5. The semiconductor device according to claim 1, wherein
the conducting pillar is made of a material selected from the group consisting of W, RuO₂, and impurity-containing polycrystalline silicon.

6. The semiconductor device according to claim 1, wherein the dielectric film is made of SrTiO₃.

7. The semiconductor device according to claim 1, wherein the lower electrode includes a lower portion extending to a bottom end of the lower electrode, the lower portion having a larger area of a cross-section parallel to a substrate plane than that of an upper portion of the lower electrode extending to a top end thereof.

8. A method for manufacturing a semiconductor device, comprising:
forming a conducting plug in a first interlayer insulating film over a semiconductor substrate;
forming a second interlayer insulating film over the conducting plug and the first interlayer insulating film;
forming a hole penetrating the second interlayer insulating film to reach the conducting plug;
forming a first conducting film over a surface including an internal wall of the hole, forming a second conducting film to fill the hole, and removing the first conducting film and the second conducting film outside the hole, thereby obtaining in the hole a lower electrode comprising a conducting pillar made of the second conducting film, and a conducting outer layer including the first conducting film covering a circumferential side surface of the conducting pillar;
removing the second interlayer insulating film to expose the lower electrode;
forming a dielectric film covering the lower electrode; and
forming a conducting film for an upper electrode on the dielectric film such that the conducting film covers the lower electrode.

9. The method for manufacturing a semiconductor device according to claim 8, further comprising:
removing a top end portion of the second conducting film in the hole to form a depression at an opening of the hole when or after removing the first conducting film and the second conducting film outside the hole;
forming a third conducting film to fill the depression; and
removing the third conducting film outside the depression,
thereby obtaining the lower electrode comprising, in the hole,
the conducting pillar made of the second conducting film, and
the conducting outer layer including the first conducting film covering the circumferential side surface of the conducting pillar, and the third conducting film covering a top surface of the conducting pillar.

10. The method for manufacturing a semiconductor device according to claim 8, wherein the second interlayer insulating film is a multilayer film comprising a lower layer insulating film extending to a bottom surface of the second interlayer insulating film, and an upper layer insulating film formed over the lower layer insulating film, the upper layer extending to a top surface of the second interlayer insulating film;
the lower layer insulating film is made of a material being able to be etched at an etching rate higher than an etching rate of the upper insulating film in a subsequent etching; and
after forming the hole in the second interlayer insulating film made up of the multilayer film to reach the conducting plug, the etching is performed in the hole to cause recessing in a side wall of the lower insulating film beyond a side wall of the upper insulating film, thereby expanding an internal diameter of a lower portion of the hole.

11. A method for manufacturing a semiconductor device, comprising:
forming a conducting plug in a first interlayer insulating film over a semiconductor substrate;
forming a second interlayer insulating film over the conducting plug and the first interlayer insulating film;
forming a hole penetrating the second interlayer insulating film to reach the conducting plug;
forming a first conducting film to fill the hole to form a conducting pillar made of the first conducting film in the hole;
removing the second interlayer insulating film to expose the conducting pillar;
forming a second conducting film covering the conducting pillar to form a lower electrode comprising the conducting pillar made of the first conducting film, and a conducting outer layer including the second conducting film covering the top surface and the circumferential side surface of the conducting pillar;
forming a dielectric film covering the lower electrode; and
forming a conducting film for an upper electrode on the dielectric film such that the conducting film covers the lower electrode.

12. The method for manufacturing a semiconductor device according to claim 11, wherein the first conducting film is an impurity-containing polycrystalline silicon film;
the second conducting film is a metal-containing film; and
the method further comprising forming a first barrier conducting film covering the exposed conducting pillar before forming the second conducting film.

13. The method for manufacturing a semiconductor device according to claim 11, wherein the conducting plug is formed using an impurity-containing polycrystalline silicon;
the first conducting film is formed using metal-containing film; and
the method further comprising forming a second barrier conducting film covering at least a bottom surface of the hole before forming the first conducting film to fill the hole, thereby obtaining in the hole a conducting pillar made up of the first conducting film, at least a bottom surface of the conducting pillar being covered with the second barrier layer.

14. The method for manufacturing a semiconductor device, according to claim 11, wherein the second interlayer insulating film is a multilayer film comprising a lower layer insulating film extending to a bottom surface of the second interlayer insulating film and an upper layer insulating film formed over the lower layer insulating film, the upper layer extending to a top surface of the second interlayer insulating film;
the lower layer insulating film is made of a material being able to be etched at an etching rate higher than an etching rate of the upper insulating film in a subsequent etching; and
after forming the hole in the second interlayer insulating film made up of the multilayer film to reach the conducting plug, the etching is performed in the hole to cause recessing in a side wall of the lower insulating film beyond a side wall of the upper insulating film, thereby expanding an internal diameter of a lower portion of the hole.
